(19) United States
(12) Patent Application Publication
(10) Pub. No.: US 2023/0333151 A1
(43) Pub. Date: Oct. 19, 2023

(54) SHOCK ALERT WARNING DEVICE AND METHOD FOR PROTECTION FROM ELECTRIC SHOCK IN A FLOODED AREA

(71) Applicant: Bender GmbH & Co. KG, Gruenberg (DE)

(72) Inventor: Julian Reitz, Gruenberg (DE)

(21) Appl. No.: 18/134,076

(22) Filed: Apr. 13, 2023

(30) Foreign Application Priority Data
Apr. 13, 2022 (DE) 10 2022 109 051.5

(51) Int. Cl. G01R 29/14; G08B 21/02

(52) U.S. Cl. CPC G01R 29/14; G08B 21/02

(57) ABSTRACT

A shock alert warning deviceand a method for protection from electric shock in a flooded areahaving electric installations are provided. An electric potential distribution is detected in the flooded areaby means of a number n of measuring probeswhich are distributed in the flooded area. Each measuring probe has a measuring potential as a potential measuring point. The measuring probeseach have a buoyant bodyhaving measuring electrodesdisposed on an outer side, electronics unit, a signal generator,anda power supply.

### TECHNICAL FIELD

The invention relates to a shock alert warning device and a method for protection from electric shock in a flooded area having electric installations.

### BACKGROUND

As a result of heavy rainfalls, rescue workers, such as firefighters, are increasingly confronted with rescue missions in flooded areas. Often rooms of private households or spaces of industrial buildings are flooded with water as a result of under-capacity sewers or rivers overflowing their banks. Directly venturing into the flooded areas often cannot be avoided in particular when saving lives. The flood water is frequently strongly contaminated, which not only causes low visibility under water but is also conducive to increased electric conductivity of the water.

In conjunction with electric installations, an increased risk potential through electric shock exists in the flooded areas. In most cases it is not known which installation parts are live, for depending on the type of building, electric installations from a simple socket to a network supply can be present at different voltage levels. Safely shutting down the electric installation, for example by the power supply company responsible, is not always possible in a timely manner. If, moreover, electrical energy storages or invertors from PV installations are installed, a shut-off often is not possible.

Not only is directly entering the flooded area dangerous, but moving around within the flooded area is equally dangerous, in particular when the person in the water unintentionally moves along electrical field lines having corresponding potential differences (voltages). If the voltage flows through the human body as a response to body parts coming into contact with the water, impaired physiological effects are to be anticipated in conjunction with the increased conductivity of the water. These effects present themselves in the form of, for example, strong involuntary muscle contractions, difficulty breathing or reversible impairments of the heart function.

For personal safety, shock testers are known from the state of the art which are to increase the safety in such rescue missions.

These shock testers, such as shock alerter P2 from the company Martina Zimmermann GmbH (https://zimmermann.expert/unser-p2/) or model DSP-HW 2 from the company Rudolph Tietzsch GmbH & Co. KG (German website: https://www.tietzsch.de/produkt/dsp-hw-2-fuer-hochwasser/; English website: https://en.tietzsch.de/produkt/dsp-hw-2-for-flooded-installations) are based on a two-pole voltage measurement with the ground potential as a reference potential. For this purpose, the mentioned devices are equipped with a ground lead having a grounding terminal or grounding rods to provide the ground potential and with a measuring probe which is held or placed in the water.

Especially the absolute necessity of a safe grounding as a measuring reference potential is seen as a disadvantage of this technical design. Depending on the nature of the soil and structural conditions in the surroundings, a grounding is neither easily possible nor electrically safe in practice, for example when the soil is dry or a connection between metal parts of the building to a foundation ground electrode is missing. As a result, trigger thresholds of the measuring devices can be shifted, whereby voltages dangerous to persons are not identified until thresholds have been far exceeded or are not identified at all in the worst case.

Another disadvantage is seen in the measuring method itself. Since only one individual potential measuring point of a possibly present electric flow field is identified using the measuring probe, this single measurement is not particularly representative for the potential distribution in the entire flooded area. At worst, no potential difference to the ground potential would be identifiable if the measuring probe (potential measuring point) were located on an equipotential surface having ground potential, comparable to a symmetrical neutral point without an N conductor connection in a three-phase network.

It also proves cumbersome that the known shock testers must either be permanently held, carried or be constantly implemented in secured places, meaning the hands are not permanently free for the actual work.

### SUMMARY

The object of the invention at hand is therefore to propose a shock alert warning device and a method for protection from electric shock in a flooded area having electric installations which both enable simplified handling in addition to a reliable identification of the danger caused by electric voltage.

This object is attained by a shock alert warning device for protection from electric shock in a flooded area having electric installations according to claim 1.

For this purpose, the shock alert warning device has a number n of measuring probes which are distributed in the flooded area and each have a measuring potential as potential measuring points for detecting an electric potential distribution in the flooded area.

In contrast to the designs known from the state of the art having only one measuring probe, the shock alert warning device proposed here has several measuring probes, which can depict an electric flow field in the flooded area owing to their spatial distribution. The electric flow field is described by an electric potential distribution in this context, the electric potential distribution being yielded from the relative reference potential, which is pre-specified by a reference probe and is independent of the ground potential, and from the measuring potentials registered by the remaining measuring probes as further potential measuring points.

The measuring probes are each made of a buoyant body, on the outer side of which several measuring electrodes are distributed on the enveloping surface of the body and each have an electrode potential. Thus, a direct contact with the water at the water’s surface is ensured, meaning the electric potentials in the close range of the corresponding measuring probe can be reliably measured.

The measuring probes each further comprise an electronics unit and a signal generator.

The electronics units process the measured electrode potentials on a digital level and can be designed differently (see below) depending on the function of the measuring probe (measuring probe with or without reference function).

The signal generators emit warnings in the form that voltage levels dangerous to persons and/or direction information on voltage changes are optically or acoustically signaled.

The measuring probes are connected to each other via connection lead sections and thus form a probe chain which floats on the water’s surface.

The connection lead sections represent both an electrical as well as mechanical connection between the measuring probes.

By designating one of the measuring probes, preferably the first or the last measuring probe of the probe chain, as the reference probe, i.e., their measuring potential is defined as the relative reference potential for identifying measuring potential differences with respect to the remaining measuring probes, the necessity of a connection to an external, possibly difficultly accessible and electrically unsafe ground point becomes immaterial.

The problem of unsafe ground connections is therefore dispensed. Moreover, the handling of a shock alert warning device of this kind during a mission is simplified significantly.

Advantageously, the electronics unit of the measuring probes not configured as the reference probe has an analog-to-digital converter for converting the electrode potentials registered at the corresponding measuring electrodes to digital signals.

With the exception of the reference probe, each measuring probe is equipped with an analog-to-digital converter to forward the registered electrode potentials in digital form and to thus make methods for digital signal processing accessible for evaluation.

Furthermore, the electronics unit of the reference probe has a microcontroller for central digital signal processing.

All evaluation processes and control processes take place centrally in the microcontroller of the reference probe.

In other advantageous designs, the microcontroller is configured to identify a measuring potential difference with respect to the reference potential at the measuring probe not configured as the reference probe.

In the microcontroller, the measuring potentials for the measuring probes not configured as the reference probe are continuously tested after start of operation to discover whether the measuring potential registered by the corresponding measuring probe has a measuring potential difference with respect to the reference potential (far-range evaluation). An exceedance of a preset measuring-potential difference threshold is indicated to the signal generator of the corresponding measuring probe via the connection lead and is optically and/or acoustically signaled there.

Furthermore, the microcontroller is configured for calculating the measuring potential for the measuring probes not configured as the reference probe from the electrode potentials registered at the measuring electrodes of the corresponding measuring probe.

For calculating the measuring potentials of each measuring probe (excluding the reference probe), a measured value representative for this measuring probe is determined as the measuring potential from the electrode potentials registered at the corresponding measuring probe, for example via averaging (near-range evaluation). The measuring potentials detected thus at the locations of the measuring probes (potential measuring points) yield the potential distribution from which further calculations, such as determining a field strength vector (gradient formation), can be derived.

Furthermore, the microcontroller is configured to calculate the direction of the largest voltage change from the potential distribution by means of gradient formation.

From the potential distribution-represented by the individual measuring potentials of the measuring probes—the direction of the largest voltage change is calculated by means of gradient formation. From the spatial change of the electric potential, i.e., of the measuring potential at the location of a specific measuring probe, the electric field strength and thus the direction of the largest voltage change can consequently be determined and be signaled by means of the signal generator. In this manner, the danger of electric current is not only identified but also located.

Furthermore, the microcontroller is configured to generate command signals for the signal generator in order to signal when a preset measuring-potential difference threshold is exceeded.

Besides digital signal processing in the scope of evaluating the registered electrode potentials, the microcontroller generates control signals which cause the signal generator of the measuring probes to signal when a preset measuring-potential difference threshold is exceeded. The preset measuring-potential difference threshold can be adapted to the danger levels.

Furthermore, the reference probe can be connected to a defined ground potential as a reference potential via a ground lead.

While the function of the reference potential is fulfilled by the relative reference potential independent of the ground potential and established by the reference probe, it is still possible to connect this reference potential to the ground potential via a ground lead.

Preferably, the reference probe has an energy storage for supplying the measuring probe with power.

The measuring probes are supplied with power via an energy storage designed as a rechargeable storage element (battery) or as a battery, the energy storage preferably being disposed in the reference probe and being connected to the remaining measuring probes via a supply lead.

Preferably, a connection lead consisting of the connection lead sections comprises a communication lead, a ground conductor and a supply lead.

The connection lead has a ground conductor which optionally can be connected to the ground potential via the ground lead.

Preferably, the communication lead is configured for transmitting data of the digital electrode potentials and the control signals.

The digital electrode potentials and the control signals are transmitted in digital form, e.g., via a communication lead implemented as a RS485, SPI bus or CAN bus.

Preferably, the buoyant bodies are spheroid and consist of transparent plastic, the signal generator being a sound converter and/or an illumination apparatus glowing through the transparent plastic having different color depictions and several illumination modes for signaling different danger levels.

The transparent plastic material allows equipping the buoyant bodies with inner illumination apparatuses which glow in different colors and with different illumination modes depending on how far a preset measuring-potential difference threshold has been exceeded, i.e., according to different danger levels; for example, a constant green light for a safe voltage level in the flooded area, blinking red light for danger and as a running light for signaling the direction of the largest voltage change (gradient).

The shock alert warning device according to the invention as described above implements the method steps described in independent claim 14. Insofar, the technical effects mentioned above and the advantages resulting therefrom pertaining to the method also pertain to the method features.

### BRIEF DESCRIPTION OF THE DRAWING FIGURES

Further advantageous embodiment features are derived from the following description and the drawings which describe a preferred embodiment of the invention by means of examples.

FIG. 1 shows a shock alert warning device according to the invention,

FIG. 2 shows a shock alert warning device according to the invention having potential distribution in a flooded area,

FIG. 3 shows a functional block diagram of the shock alert warning device according to the invention,

FIG. 4 shows a simulation of the potential distribution with a socket under water,

FIG. 5 shows a simulation of the potential distribution with two sockets under water, and

FIG. 6 shows a simulation of the potential distribution with a socket having only one active conductor under water.

### DETAILED DESCRIPTION

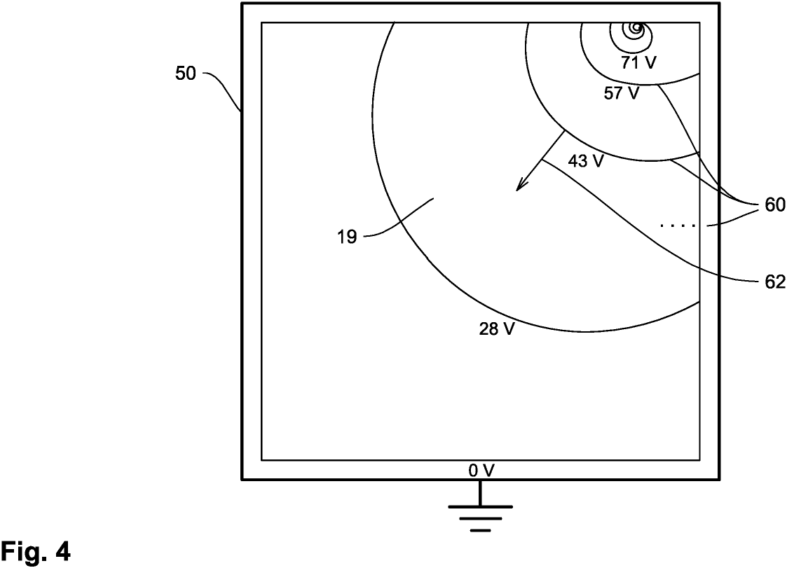

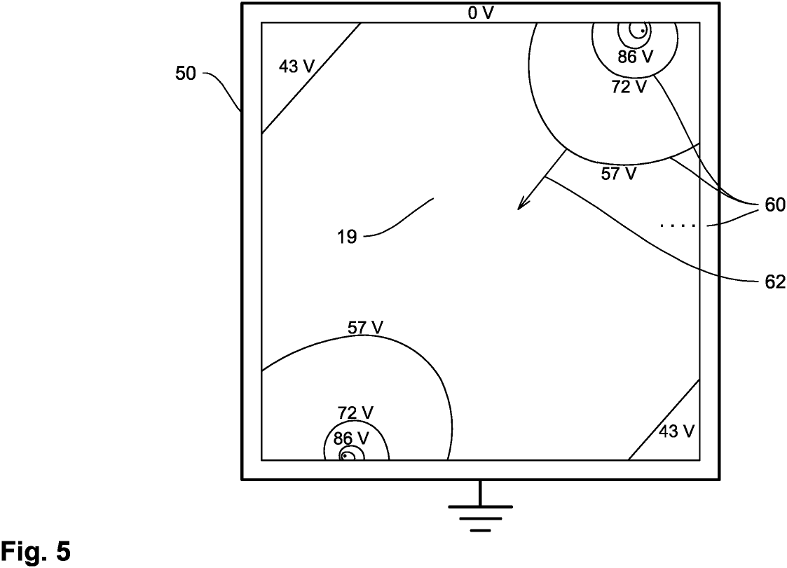

In order to clarify the task of the invention at hand, FIGS. 4 to 6 initially show simulation results of distributions of electric potential 19 in an area 50 flooded with contaminated water. A space having the dimensions 5 m x 5 m flooded with contaminated water serves as a basis, one (FIG. 4) or two (FIG. 5) 230 V sockets and a 230 V socket having only one active conductor (FIG. 5) are reconstructed as a voltage source in the space.

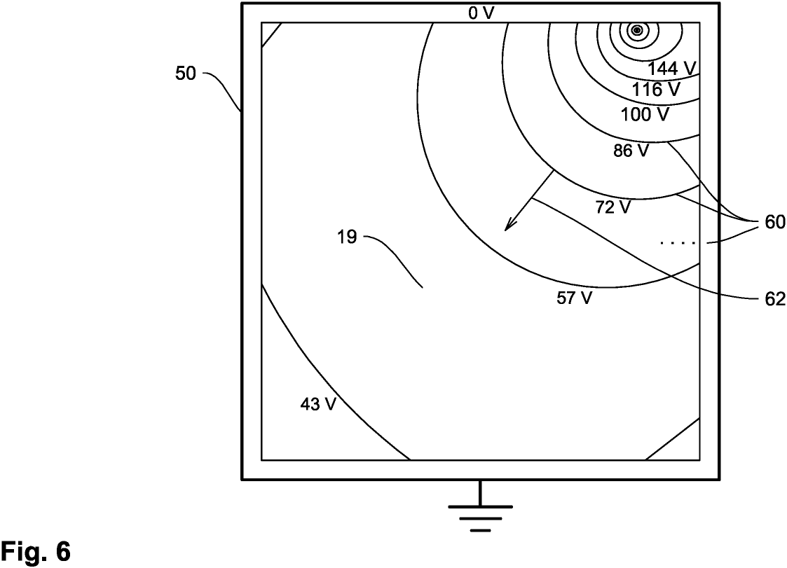

In particular in FIG. 4 and FIG. 6 with only one voltage source—viewed as a point source—a nearly circular shape of potential distribution 19 having equipotential lines 60 and a gradient 62 of the electric field strength perpendicular to equipotential lines 60 is identifiable.

Voltage levels dangerous to persons are achieved over extensive areas under these circumstances. Reliably identifying the potential differences (voltages) is therefore of the utmost necessity.

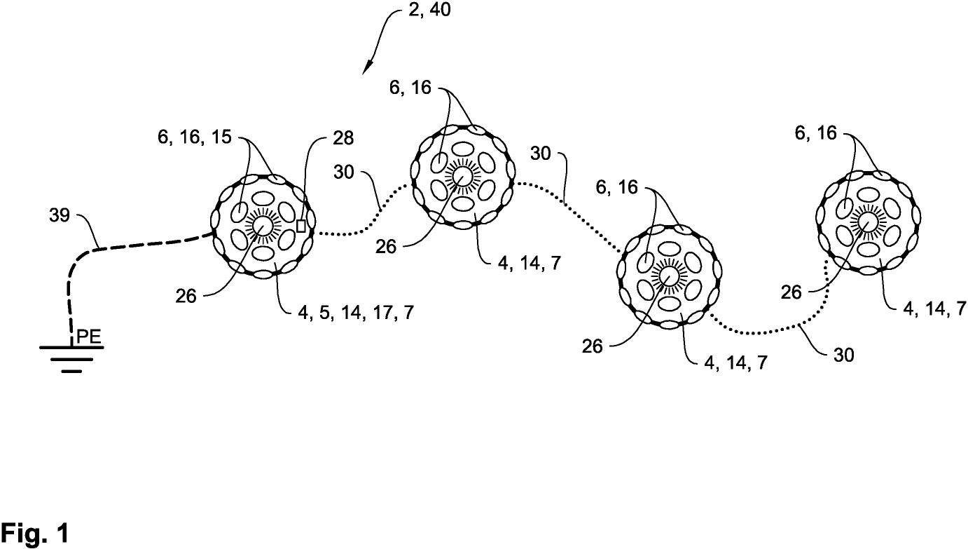

FIG. 1 shows a shock alert warning device 2 according to the invention having n = 4 measuring probes 4 which are connected to each other via connection lead sections 30 to form a probe chain 40. The distances between individual measuring probes 4 should be between 0.5 m and 2 m. The number of measuring probes 4 and the distances, however, can vary depending on the mission’s location.

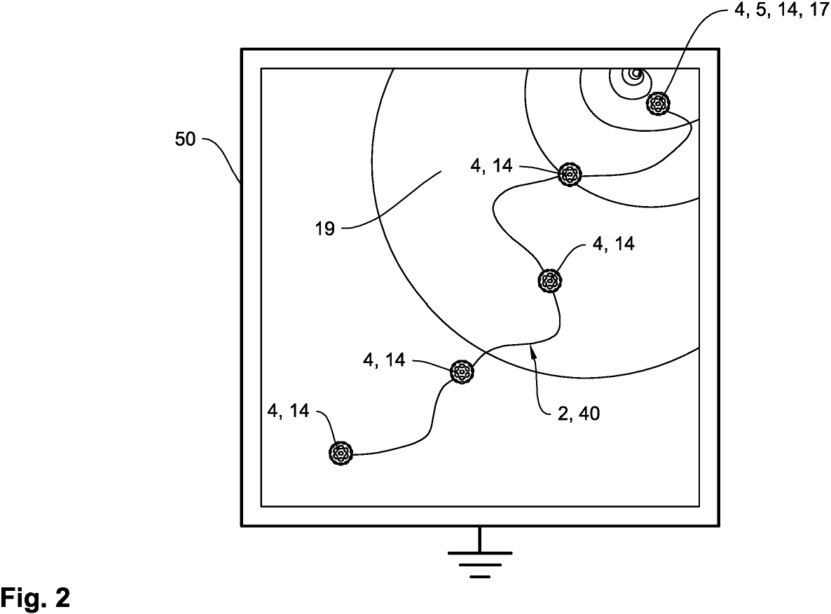

Measuring probes 4 are designed as buoyant bodes 7 on the outer side of each of which measuring electrodes 6 are affixed which ensure direct electric contact with the water in flooded area 50 (FIG. 2). Measuring electrodes 6 should be made of stainless metal, such as stainless steel or brass.

Measuring probes 4 are preferably spheroid and consist of transparent plastic, meaning a signal generator 26 located in the interior of measuring probe 4 and designed as an illumination apparatus can send warnings visible from the outside.

Each measuring electrode 6 of each measuring probe 4 has a specific electrode potential 16, one of the measuring probes 4 acting as a reference probe 5 whose measuring electrodes 6 as reference electrodes 15 all have an equal electrode potential 16, which corresponds to a relative reference potential 17 as measuring potential 14 of reference probe 5 without a connection to a ground PE.

Even though the provision of a relative reference potential 17 independent of ground potential PE represents an essential aspect of the invention, it is possible to ground relative reference potential 17 to an absolute reference potential having ground potential PE by means of a ground conductor 39.

Measuring probes 4 and the connection lead consisting of connection lead sections 30 should have protection class IP68 (dust and water-tight).

The connection lead sections can be reinforced by inserts and simultaneously act as flexible mechanical connections between the measuring probes.

FIG. 2 shows shock alert warning device 2 in a flooded area 50 having a simulated voltage source under water and resulting potential distribution 19. At the locations of measuring probes 4, a measuring potential 14 is detected in the electric flow field according to settling potential distribution 19 and/or is pre-specified at the location of reference probe 5 via relative reference potential 17.

Probe chain 40 is first thrown in the water, for example secured to a line. If probe chain 40 does not emit a warning (alarm), flooded area 50 can be entered at this location. If one moves deeper into flooded area 50, probe chain 40 is constantly waved around by the moving person. If in doing so voltage levels dangerous to persons are identified, an alarm is emitted. The person should not move on.

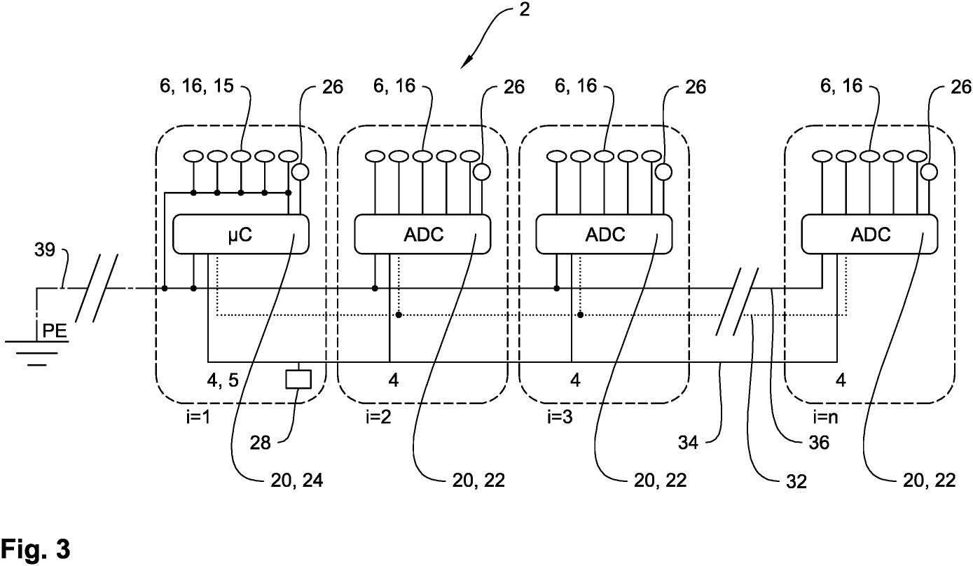

In FIG. 3, a functional block diagram of shock alert warning device 2 having n measuring probes 4 is shown.

Measuring probe 4 at this location i = 1 forms reference probe 5 and provides electrode potential 16 at reference probe 5 via a ground conductor 36 by means of measuring electrodes 6 acting as reference electrodes 15, electrode potential 16 corresponding to relative reference potential 17 (FIGS. 1, 2).

Subsequent measuring probes 4 at the locations i = 2 to n register electrode potential 16 prevalent there via their corresponding measuring electrodes 6 and forward it to microcontroller 24 of reference probe 5 via communication lead 32 after analog-to-digital conversion 22 (ADC).

Microcontroller 24 detects corresponding measuring potential 14 (FIGS. 1, 2) at the locations i = 2 to n by calculating a representative value for measuring potential 14 as the potential measuring point, e.g., by averaging in conjunction with digital filtering options, from electrode potentials 16 registered there in the near range (around the locations i = 2 to n) (near-range evaluation). Measuring potentials 14 detected thus spatially depict potential distribution 19, meaning measuring potential differences are safely identified (far-range evaluation).

Via a supply lead 34, measuring probes 4 are supplied with power by energy storage 28 of reference probe 5.

The combination of near-range evaluation and far-range evaluation can be used to calculate gradient 62 of electric field strength (FIGS. 4 to 6) starting from the depiction of potential distribution 19. This allows identifying movement directions dangerous to persons (along gradient 62) and less dangerous movement directions (along equipotential lines 60) of the acting person in advance of the mission.

1. A shock alert warning devicefor protection from electric shock in a flooded areahaving electric installations, comprising:
a number n of measuring probeswhich are distributed in the flooded area wherein each measuring probe has (a) a measuring potentialas a potential measuring point for detecting an electric potential distribution in the flooded area, (b) a buoyant bodyhaving measuring electrodes disposed on an outer side and having an electrode potential, (c) an electronics unit and (d) a signal generatorand wherein the measuring probes are connected to each other via connection lead sections to form a buoyant probe chain,
one of the measuring probesbeing configured as a reference probe for establishing a relative reference potentialas a measuring potentialwithout a connection to a ground potential.

2. The shock alert warning device according to claim 1, wherein
the electronics unitof the measuring probesnot configured as a reference probehas an analog-to-digital converterfor converting the electrode potentialsregistered at the measuring electrodesto digital signals.

3. The shock alert warning device according to claim 2, wherein
the electronics unitof the reference probehas a microcontroller for central digital signal processing.

4. The shock alert warning device according to claim 3, wherein
the microcontrolleris configured for identifying a measuring potential difference with respect to the reference potentialat the measuring probesnot configured as the reference probe.

5. The shock alert warning device according to claim 4, wherein
the microcontrolleris configured for calculating the measuring potential for the measuring probesnot configured as the reference probefrom the electrode potentialregistered at the measuring electrodesof the corresponding measuring probes.

6. The shock alert warning device according to claim 5, wherein
the microcontrolleris configured to calculate the direction of the largest voltage change by means of forming gradients from the potential distribution.

7. The shock alert warning device according to claim 6, wherein
the microcontrolleris configured for generating control signalsfor the signal generatorin order to signal when a preset measuring-potential difference threshold is exceeded.

8. The shock alert warning device according to claim 7, wherein
the reference probeis connected to a defined ground potential as a reference potentialvia a ground lead.

9. The shock alert warning device according to claim 7, wherein
the reference probehas an energy storagefor supplying power to the measuring probes.

10. The shock alert warning device according to claim 7, wherein
a connection lead consisting of connection lead sectionshas a communication lead, a ground conductorand a supply lead.

11. The shock alert warning device according to claim 10, wherein
the communication leadis configured for transmitting data of the digital electrode potentials and the control signals.

12. The shock alert warning device according to claim 11, wherein
the buoyant bodiesare spheroid and consist of transparent plastic.

13. The shock alert warning device according to claim 12, wherein
the signal generatoris a sound converter and/or an illumination apparatus having different color depictions and several light modes for signaling different danger levels.

14. A method for protection from electric shock in a flooded areahaving electric installations, the method comprising:
detecting an electric potential distributionin the flooded areaby means of a number n of measuring probeswhich are distributed in the flooded area and wherein each measuring probe has a measuring potentialas a potential measuring point and each consists of a buoyant bodyhaving (a) measuring electrodesdisposed on an outer side and having electrode potentials, (b) an electronics unitand (c) a signal generatorand efwherein a power supply is connected to each measuring probe by connection lead sectionsto form a buoyant probe chain,
the measuring potentialof a reference probebeing established as a relative reference potentiawithout being connected to a ground potential.

15. The method according to claim 14, further including converting, at the measuring probes not configured as reference probes,
the electrode potentials registered by the corresponding measuring probes to digital sounds in the electronics unitof the measuring probesnot configured as a reference probeby means of an analog-to-digital converter.

16. The method according to claim 15, further including implementing
digital signal processing steps centrally in the electronics unitof the reference probevia a microcontroller.

17. The method according to claim 16, further including measuring, at the measuring probes not configured as a reference probe,
potential differences occurring with respect to the reference potential as identified by the microcontroller.

18. The method according to claim 17, further including calculating
the measuring potentialfor each measuring probenot configured as a reference probe from the electrode potentialsregistered at the measuring electrodesof the corresponding measuring probe.

19. The method according to claim 18, further including calculating
the direction of the largest voltage change in the microcontrollerfrom the potential distributionby means of gradient formation.

20. The method according to claim 19, further including generating
control signals by the microcontrollerfor the signal generator in order to signal when a preset measuring-potential difference threshold is exceeded.

21-24. (canceled)
